(19) United States
(12) Patent Application Publication
(10) Pub. No.: US 2025/0232820 A1
(43) Pub. Date: Jul. 17, 2025

(54) MEMORY DEVICE

(71) Applicant: SAMSUNG ELECTRONICS CO., LTD., Suwon-si (KR)

(72) Inventors: Hanmin NAM, Suwon-si (KR); Seungyeon KIM, Suwon-si (KR); Jeunghwan PARK, Suwon-si (KR); Hyunkook PARK, Suwon-si (KR); Changyeon YU, Suwon-si (KR); Seokhyeon CHAE, Suwon-si (KR)

(73) Assignee: SAMSUNG ELECTRONICS CO., LTD., Suwon-si (KR)

(21) Appl. No.: 18/968,515

(22) Filed: Dec. 4, 2024

(30) Foreign Application Priority Data
Jan. 15, 2024 (KR) 10-2024-0006298

(51) Int. Cl. G11C 16/32; G11C 16/04; G11C 16/08

(52) U.S. Cl. CPC G11C 16/32; G11C 16/0483; G11C 16/08

(57) ABSTRACT

A memory device includes: a first driving signal line group including at least two or more first driving signal lines configured to be driven at a first timing; a second driving signal line group including at least two or more second driving signal lines configured to be driven at a second timing different from the first timing; and an additional signal line group including an additional signal line configured to be floating-processed at the first timing or the second timing, wherein the first driving signal line group and the second driving signal line group are connected to a memory cell block via a pass transistor circuit.

### CROSS-REFERENCE TO RELATED APPLICATION

This application is based on and claims priority under 35 U.S.C. § 119 to Korean Patent Application No. 10-2024-0006298, filed on Jan. 15, 2024, in the Korean Intellectual Property Office, the disclosure of which is incorporated by reference herein in its entirety.

### BACKGROUND

The present disclosure relates to a memory device, and more particularly, to a wiring structure of driving signal lines connected to a pass transistor block included in a memory device.

Volatile memory devices have a fast write and read speed but may lose data stored therein if power supply is cut off. Nonvolatile memory devices have a relatively slow write and read speed but may maintain data stored therein even if power supply is cut off. Therefore, nonvolatile memory devices may be used to store data that has to be maintained regardless of whether power is supplied. The nonvolatile memory devices may include read-only memory (ROM), mask ROM (MROM), programmable ROM (PROM), erasable programmable ROM (EPROM), electrically erasable programmable ROM (EEPROM), flash memory, phase-change random access memory (PRAM), magnetic RAM (MRAM), resistive RAM (RRAM), ferroelectric RAM (FRAM), and the like. There are two types of flash memory, NOR type and NAND type.

Among nonvolatile memory devices, a NAND flash memory device is frequently used as a data storage device. The NAND flash memory device may transfer operating voltages to memory cells via a row decoder. According to an embodiment, a driving signal line may be connected to the row decoder.

### SUMMARY

One or more embodiments provide a memory device that may decrease an ICC peak current between driving signal lines.

According to an aspect of an example embodiment, a memory device includes a first driving signal line group including at least two or more first driving signal lines configured to be driven at a first timing; a second driving signal line group including at least two or more second driving signal lines configured to be driven at a second timing different from the first timing; and an additional signal line group including an additional signal line configured to be floating-processed at the first timing or the second timing, wherein the first driving signal line group and the second driving signal line group are connected to a memory cell block via a pass transistor circuit.

According to an aspect of an example embodiment, a memory device includes a memory cell array comprising a plurality of memory blocks; a plurality of driving signal lines respectively corresponding to a plurality of word lines stacked in a vertical direction; a first additional signal line; and a pass transistor circuit connected between the plurality of driving signal lines and the memory cell array, wherein a first pass transistor included in the pass transistor circuit is provided as a structure sharing an active region with a second pass transistor adjacent to the first pass transistor, a first driving signal line of the plurality of driving signal lines is configured to be driven at a first timing and is connected to the active region of the first pass transistor and the second pass transistor, and in a metal wiring structure of the first driving signal line, and the first additional signal line is configured to be floating at the same timing as the first driving signal line and is arranged on a second line adjacent to the first driving signal line.

According to an aspect of an example embodiment, a memory device includes a memory device including a memory cell array including a plurality of memory blocks; a plurality of driving signal lines respectively corresponding to a plurality of word lines stacked in a vertical direction; and a pass transistor circuit connected between the plurality of driving signal lines and the memory cell array, wherein each of a plurality of pass transistor blocks included in the pass transistor circuit comprises two pass transistors sharing an active region, the plurality of pass transistor blocks including a respective plurality of active regions, different driving signal lines are respectively connected to the plurality of active regions of the plurality of pass transistor blocks, and wherein the plurality of driving signal lines comprises: a first driving signal line connected to a first active region and driven at a first timing; a second driving signal line connected to a second active region and driven at a second timing; a third driving signal line connected to a third active region and driven at the first timing; a fourth driving signal line connected to a fourth active region and driven at the second timing, and a first additional signal line adjacent to at least one of the first driving signal line and the third driving signal line.

### BRIEF DESCRIPTION OF THE DRAWINGS

The above and/or other aspects will be more clearly understood from the following detailed description taken in conjunction with the accompanying drawings, in which:

FIG. 1 is a block diagram illustrating a memory device according to an embodiment;

FIG. 2 is a perspective view schematically illustrating a structure of a memory device according to an embodiment;

FIG. 3 is a perspective view illustrating a memory cell array according to an embodiment;

FIG. 4 is a block diagram illustrating a row decoder, a pass transistor circuit, and memory blocks, according to an embodiment;

FIG. 5 is a circuit diagram illustrating a pass transistor circuit and a first memory block, according to an embodiment;

FIG. 6 is a top view illustrating a plurality of pass transistor blocks included in a pass transistor circuit and word line driving signal lines corresponding to the plurality of pass transistor blocks, according to an embodiment;

FIG. 7 is a top view illustrating an arrangement structure of driving signal lines connected to a plurality of pass transistor blocks, according to an embodiment;

FIG. 8 is a top view illustrating an arrangement structure in which a plurality of driving signal lines corresponding to a plurality of pass transistor blocks are arranged along certain track lines, according to an embodiment;

FIG. 9 is a top view illustrating an arrangement structure of driving signal lines, according to an embodiment;

FIG. 10 is a top view illustrating an arrangement structure of additional signal lines, according to an embodiment;

FIG. 11 is a top view illustrating an arrangement structure of additional signal lines, according to an embodiment;

FIG. 12 is a top view illustrating an arrangement structure of additional signal lines, according to an embodiment;

FIG. 13A illustrates coupling capacitance between adjacent signal lines;

FIG. 13B shows timing diagrams illustrating a read operation of an additional signal line, according to an embodiment; and

FIG. 14 is a block diagram illustrating an example in which a memory device according to some embodiments is applied to a solid-state drive (SSD) system.

### DETAILED DESCRIPTION

Hereinafter, various example embodiments are described with reference to the accompanying drawings.

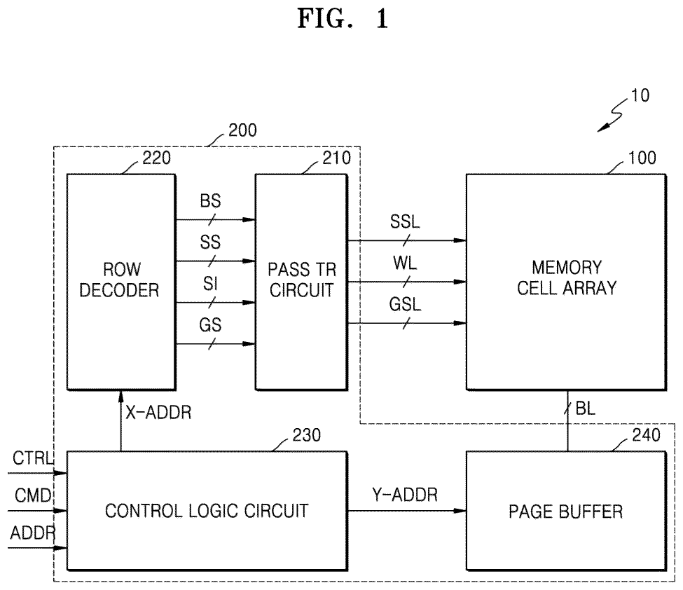

FIG. 1 is a block diagram illustrating a memory device 10 according to an embodiment.

Referring to FIG. 1, the memory device 10 may include a memory cell array 100 and a peripheral circuit 200, wherein the peripheral circuit 200 may include a pass transistor circuit 210, a row decoder 220, a control logic circuit 230, and a page buffer 240. The peripheral circuit 200 may further include a voltage generator, a data input-output circuit, an input-output interface, a temperature sensor, a command decoder, an address decoder, or the like. In one or more embodiments, the memory device 10 may be a nonvolatile memory device, and hereinafter, the term “memory device” indicates a nonvolatile memory device.

The memory cell array 100 may be connected to the pass transistor circuit 210 through word lines WL, string select lines SSL, and ground select lines GSL and connected to the page buffer 240 through bit lines BL. The memory cell array 100 may include a plurality of memory cells, e.g., a plurality of flash memory cells. Hereinafter, embodiments are described in detail by assuming that the plurality of memory cells are NAND flash memory cells. However, embodiments are not limited thereto, and in some embodiments, the plurality of memory cells may be resistive memory cells, such as resistive random access memory (ReRAM), phase change RAM (PRAM), or magnetic RAM (MRAM).

In an embodiment, the memory cell array 100 may include a three-dimensional memory cell array, the three-dimensional memory cell array may include a plurality of NAND strings, and each NAND string may include memory cells connected to word lines vertically stacked on a substrate. However, embodiments are not limited thereto, and in some embodiments, the memory cell array 100 may include a two-dimensional memory cell array, wherein the two-dimensional memory cell array may include a plurality of NAND strings arranged in the row and column directions.

The control logic circuit 230 may generate various kinds of control signals to program data to the memory cell array 100, read data from the memory cell array 100, or erase data stored in the memory cell array 100, based on a command CMD, an address ADDR, and a control signal CTRL. For example, the control logic circuit 230 may output a row address X-ADDR and a column address Y-ADDR. By doing this, the control logic circuit 230 may generally control various operations in the memory device 10.

In response to the row address X-ADDR, the row decoder 220 may output, to block select signal lines BS, a block select signal for selecting one of a plurality of memory blocks. In addition, in response to the row address X-ADDR, the row decoder 220 may output, to word line driving signal lines SI, a word line driving signal for selecting one of the word lines WL of the selected memory block, output, to string select line driving signal lines SS, a string select line driving signal for selecting one of the string select lines SSL, and output, to ground select line driving signal lines GS, a ground select line driving signal for selecting one of the ground select lines GSL. The page buffer 240 may select some of the bit lines BL in response to the column address Y-ADDR. Particularly, the page buffer 240 may operate as a write driver or a sense amplifier according to an operation mode.

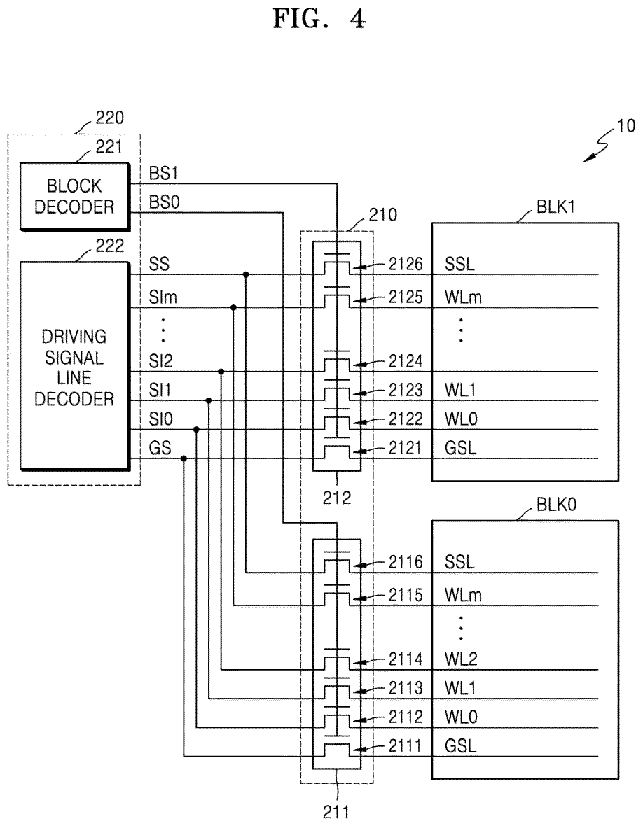

The pass transistor circuit 210 may be connected to the row decoder 220 through the block select signal lines BS, the string select line driving signal lines SS, the word line driving signal lines SI, and the ground select line driving signal lines GS. The string select line driving signal lines SS, the word line driving signal lines SI, and the ground select line driving signal lines GS may be referred to as “driving signal lines”. The pass transistor circuit 210 may include a plurality of pass transistors (e.g., 2111 to 2126 of FIG. 4), wherein the pass transistor circuit 210 may be controlled by block select signals received through the block select signal lines BS and may provide string select line driving signals, word line driving signals, and ground select line driving signals to the string select lines SSL, the word lines WL, and the ground select lines GSL, respectively.

According to an embodiment, the pass transistor circuit 210 may include a plurality of pass transistor blocks each including pass transistors sharing an active region. According to an embodiment, a pass transistor block may include at least two pass transistors sharing an active region. According to one or more embodiments, a word line driving signal line may be connected to an active region shared by at least two pass transistors included in a pass transistor block. Word line driving signal lines may be connected to the plurality of pass transistor blocks, respectively. The word line driving signal lines may have respective driving timings. According to one or more embodiments, a pass transistor block may include two pass transistors sharing an active region, wherein the gates of the two pass transistors sharing the active region may be turned on in response to different block select signals, respectively. Accordingly, when any one of a plurality of memory blocks is selected, there may exist a plurality of word line driving signal lines corresponding to the selected memory block. There may exist separated word line driving signal lines each being connected to the active area of each pass transistor for selecting a certain word line of the any one of the plurality of memory blocks. Some of the separated word line driving signal lines may be driven at the same timing and the other some of the separated word line driving signal lines may be driven at a different timing. According to one or more embodiments, in a metal wiring structure of a plurality of word line driving signal lines, by arranging word line driving signal lines driven at the same timing to be adjacent to each other, the alternating current (AC) capacitance between a word line driving signal line and an adjacent line when driving the word line driving signal line may be reduced, thereby reducing an ICC peak value.

According to an embodiment, the pass transistor circuit 210 may include six (2*3) pass transistor blocks corresponding to four memory blocks adjacent to each other in a first direction. The length of the six (2*3) pass transistor blocks in the first direction may be substantially the same as the length (i.e., the four-block height) of the four memory blocks in the first direction. For example, the pass transistor circuit 210 may include six (2*3) pass transistor blocks corresponding to four memory blocks adjacent to each other. According to an embodiment, the pass transistor circuit 210 may include three pass transistor blocks adjacent to each other in the first direction and three pass transistor blocks adjacent to each other in a second direction that is perpendicular to the first direction, the six pass transistor blocks corresponding to four memory blocks adjacent to each other. Embodiments are not limited thereto, and the pass transistor circuit 210 may include N pass transistor blocks corresponding to four memory blocks adjacent to each other. According to an embodiment, N may be a natural number greater than or equal to 2.

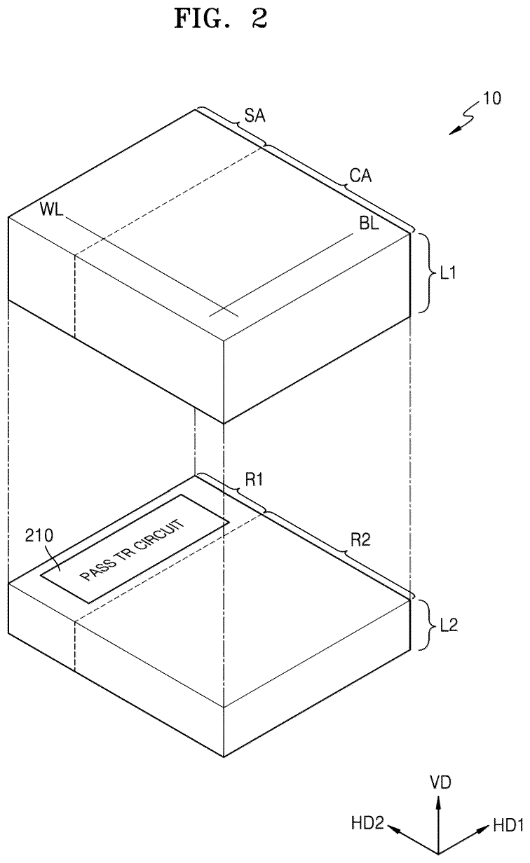

Along with the development of a semiconductor process, as the number of steps of memory cells included in the memory cell array 100 increases, in other words, as the number of word lines WL stacked in the vertical direction increases, the number of pass transistors configured to drive the word lines WL increases, thereby increasing the area occupied by the pass transistor circuit 210. According to an embodiment, the peripheral circuit 200 may be on or beneath the memory cell array 100 in the vertical direction, and in particular, the pass transistor circuit 210 may be on or beneath a stair area of the word lines WL in the vertical direction. By doing this, the area occupied by the pass transistor circuit 210 overlaps the stair area of the word lines WL in the vertical direction, and thus, an increase in the chip size of the memory device 10 may be prevented regardless of an increase in the number of pass transistors according to an increase in the number of stacked layers of the word lines WL. This is described in more detail with reference to FIG. 2.

FIG. 2 is a perspective view schematically illustrating a structure of the memory device 10 according to an embodiment.

Referring to FIGS. 1 and 2, the memory device 10 may include a first semiconductor layer L1 and a second semiconductor layer L2, wherein the first semiconductor layer L1 may be stacked on the second semiconductor layer L2 in a vertical direction VD. Particularly, the second semiconductor layer L2 may be beneath the first semiconductor layer L1 in the vertical direction VD, and accordingly, the second semiconductor layer L2 may be closer to a substrate than the first semiconductor layer L1. In an embodiment, the memory cell array 100 may be formed in the first semiconductor layer L1 and the peripheral circuit 200 may be formed in the second semiconductor layer L2. Accordingly, the memory device 10 may have a structure, i.e., a cell over periphery (CoP) structure, in which the memory cell array 100 is on a partial peripheral circuit.

The first semiconductor layer L1 may include a cell area CA and a stair area SA, wherein a plurality of memory cells may be in the cell area CA. In the first semiconductor layer L1, the bit lines BL may extend in a first horizontal direction HD1 and the word lines WL may extend in a second horizontal direction HD2. One ends of the word lines WL may be implemented in a stair shape, and in the specification, an area including the word lines WL of a stair shape in the first semiconductor layer L1 is referred to as “stair area SA” or “word line extension area”.

The second semiconductor layer L2 may include a substrate, wherein the peripheral circuit 200 may be formed in the second semiconductor layer L2 by forming, on the substrate, semiconductor devices, such as a transistor, and a pattern for wiring devices. After forming the peripheral circuit 200 in the second semiconductor layer L2, the first semiconductor layer L1 including the memory cell array 100 may be formed and patterns for electrically connecting the word lines WL and the bit lines BL of the memory cell array 100 to the peripheral circuit 200 formed in the second semiconductor layer L2 may be formed. The second semiconductor layer L2 may include a first area R1 corresponding to the stair area SA and a second area R2 corresponding to the cell area CA. In an embodiment, the pass transistor circuit 210 may be in the first area R1, but embodiments are not limited thereto.

As described above, according to embodiments, the memory device 10 may have a CoP structure and the pass transistor circuit 210 may be beneath the stair area SA. According to an embodiment, a plurality of word line driving signal lines connected to a plurality of pass transistor blocks included in the pass transistor circuit 210 may extend in the first horizontal direction HD1.

A memory device according to one or more embodiments may be applied to a case where memory blocks are shared in a multi-step structure of pass transistors. According to an embodiment, driving signal lines may be arranged in a bit line direction, i.e., the first horizontal direction HD1, crossing all memory blocks so as to be connected to at least some memory blocks in a memory block area. When the driving signal lines are arranged, an additional signal line may be arranged at a side of at least one of adjacent driving signal lines. The additional signal line may be floating-processed in a word line setup interval to reduce an ICC peak current of a driving signal line and reduce a rising time. When the driving signal lines are arranged, a driving signal line to which a similar waveform is applied may be arranged at a side of at least one of adjacent driving signal lines. The driving signal line to which a similar waveform is applied may indicate a driving signal line driven at the same timing as an adjacent driving signal line. Alternatively, the driving signal line to which a similar waveform is applied may indicate a driving signal line having the same voltage or the same waveform in a setup/hold/discharge interval as an adjacent driving signal line. According to an embodiment, an additional signal line adjacent to driving signal lines may be floating-processed or boosting-processed. Boosting processing may indicate controlling a signal line to have the same waveform at the same timing as a driving signal line.

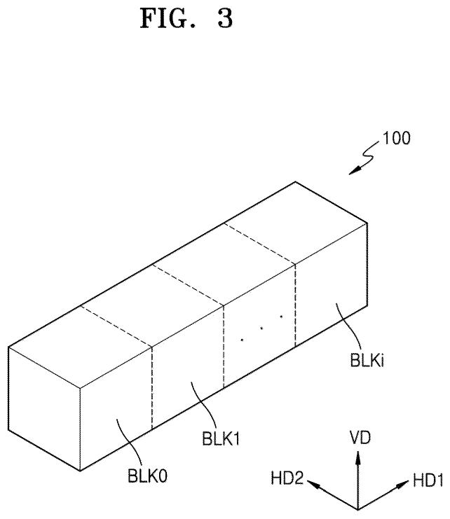

FIG. 3 is a perspective view illustrating the memory cell array 100 according to an embodiment.

Referring to FIG. 3, the memory cell array 100 may include a plurality of memory blocks BLK0 to BLKi, wherein i is a positive integer. Each of the plurality of memory blocks BLK0 to BLKi may have a three-dimensional structure (or a vertical structure). Particularly, each of the plurality of memory blocks BLK0 to BLKi may include a plurality of NAND strings extending in the vertical direction VD. Herein, the plurality of NAND strings may be spaced apart by a certain distance from each other in the first and second horizontal directions HD1 and HD2. The plurality of memory blocks BLK0 to BLKi may be selected by the row decoder 220 (see FIG. 1). For example, the row decoder 220 may select a memory block corresponding to a block address from among the plurality of memory blocks BLK0 to BLKi.

FIG. 4 is a block diagram illustrating the row decoder 220, the pass transistor circuit 210, and first and second memory blocks BLK0 and BLK1 according to an embodiment.

Referring to FIG. 4, the memory device 10 may include the pass transistor circuit 210, wherein the pass transistor circuit 210 may include a plurality of pass transistor circuits respectively corresponding to a plurality of memory blocks. The first and second memory blocks BLK0 and BLK1 may be arranged adjacent to each other, and each of the first and second memory blocks BLK0 and BLK1 may include a ground select line GSL, a plurality of word lines WL0 to WLm, and a string select line SSL, wherein m is a positive integer.

The row decoder 220 may include a block decoder 221 and a driving signal line decoder 222. The pass transistor circuit 210 may include a pass transistor circuit 211 corresponding to the first memory block BLK0 and a pass transistor circuit 212 corresponding to the second memory block BLK1. The pass transistor circuit 211 may include a plurality of pass transistors 2111 to 2116, and the pass transistor circuit 212 may include a plurality of pass transistors 2121 to 2126.

The block decoder 221 may be connected to the pass transistor circuit 211 through a first block select signal line BS0 and connected to the pass transistor circuit 212 through a second block select signal line BS1. The first block select signal line BS0 may be connected to the gates of the plurality of pass transistors 2111 to 2116. For example, if a first block select signal provided through the first block select signal line BS0 is enabled, the plurality of pass transistors 2111 to 2116 may be turned on, and accordingly, the first memory block BLK0 may be selected. In addition, the second block select signal line BS1 may be connected to the gates of the plurality of pass transistors 2121 to 2126. For example, if a second block select signal provided through the second block select signal line BS1 is enabled, the plurality of pass transistors 2121 to 2126 may be turned on, and accordingly, the second memory block BLK1 may be selected.

The driving signal line decoder 222 may be connected to the pass transistor circuits 211 and 212 through a string select line driving signal line SS, word line driving signal lines SI0 to SIm, and a ground select line driving signal line GS. Particularly, the string select line driving signal line SS, the word line driving signal lines SI0 to SIm, and the ground select line driving signal line GS may be respectively connected to the sources of the plurality of pass transistors 2111 to 2116 and respectively connected to the sources of the plurality of pass transistors 2121 to 2126.

The pass transistor circuit 211 may be connected to the first memory block BLK0 through the ground select line GSL, the plurality of word lines WL0 WLm, and the string select line SSL. The pass transistor 2111 may be connected between the ground select line driving signal line GS and the ground select line GSL. The pass transistors 2112 to 2115 may be connected between the word line driving signal lines SI0 to SIm and the plurality of word lines WL0 to WLm, respectively. The pass transistor 2116 may be connected between the string select line driving signal line SS and the string select line SSL. For example, if the first block select signal is enabled, the plurality of pass transistors 2111 to 2116 may provide driving signals provided through the ground select line driving signal line GS, the word line driving signal lines SI0 to SIm, and the string select line driving signal line SS to the ground select line GSL, the plurality of word lines WL0 to WLm, and the string select line SSL, respectively. The description of the pass transistor circuit 211 may also be applied to the pass transistor circuit 212 and is thus not repeated herein.

According to an embodiment, any one of the plurality of pass transistors 2111 to 2116 included in the pass transistor circuit 211 corresponding to the first memory block BLK0 and any one of the plurality of pass transistors 2121 to 2126 included in the pass transistor circuit 212 corresponding to the second memory block BLK1 may be included in a pass transistor block sharing an active region. According to an embodiment, there may be disclosed a pass transistor circuit sharing different memory blocks by a structure of a pass transistor block sharing an active region.

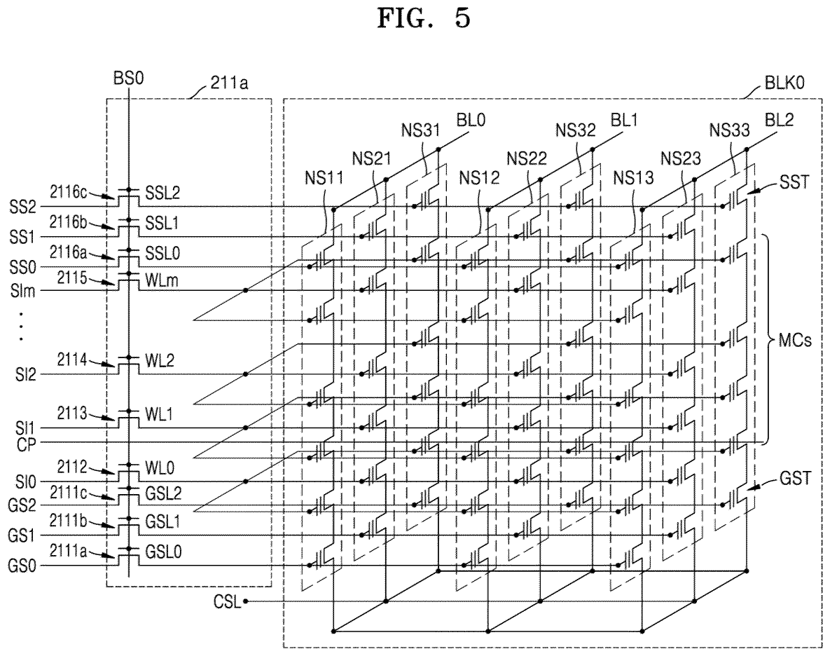

FIG. 5 is a circuit diagram illustrating a pass transistor circuit 211a and the first memory block BLK0 according to an embodiment.

Referring to FIG. 5, the pass transistor circuit 211a may correspond to an implementation example of the pass transistor circuit 211 of FIG. 4. In an embodiment, the pass transistor circuit 212 may be implemented to be substantially similar to the pass transistor circuit 211a, and the second memory block BLK1 may be implemented to be substantially similar to the first memory block BLK0. The first memory block BLK0 may include a plurality of NAND strings NS11 to NS33, the plurality of word lines WL0 to WLm, a plurality of bit lines BL0 to BL2, a plurality of ground select lines GSL0 to GSL2, a plurality of string select lines SSL0 to SSL2, and a common source line CSL. Herein, the number of NAND strings, the number of word lines, the number of bit lines, the number of ground select lines, and the number of string select lines may be variously modified according to embodiments.

The NAND strings NS11, NS21, and NS31 may be provided between the bit line BL0 and the common source line CSL, the NAND strings NS12, NS22, and NS32 may be provided between the bit line BL1 and the common source line CSL, and the NAND strings NS13, NS23, and NS33 may be provided between the bit line BL2 and the common source line CSL. Each NAND string (e.g., NS33) may include a string select transistor SST, a plurality of memory cells MCs, and a ground select transistor GST, which are connected in series.

The string select transistor SST may be connected to a corresponding string select line SSL0, SSL1, or SSL2. The plurality of memory cells MCs may be connected to the plurality of word lines WL0 to WLm, respectively. The ground select transistor GST may be connected to a corresponding ground select line GSL0, GSL1, or GSL2. The string select transistor SST may be connected to a corresponding bit line BL0, BL1, or BL2, and the ground select transistor GST may be connected to the common source line CSL.

In an embodiment, word lines (e.g., WL1) at the same height, i.e., at the same level, may be commonly connected, the plurality of string select lines SSL0 to SSL2 may be separated from each other, and the plurality of ground select lines GSL0 to GSL2 may also be separated from each other. Although FIG. 5 shows that three string select lines SSL0 to SSL2 share word lines at the same height, embodiments are not limited thereto. For example, two string select lines may share word lines at the same height. As another example, four string select lines may share word lines at the same height.

The pass transistor circuit 211a may include pass transistors 2111a to 2111c respectively connected to the plurality of ground select lines GSL0 to GSL2, pass transistors 2112 to 2115 respectively connected to the plurality of word lines WL0 to WLm, and pass transistors 2116a to 2116c respectively connected to the plurality of string select lines SSL0 to SSL2. The pass transistors 2111a to 2111c, 2112 to 2115, and 2116a to 2116c may be turned on in response to the first block select signal provided through the first block select signal line BS0 and may provide driving signals provided through string select line driving signal lines SS0 to SS2, the word line driving signal lines SI0 to SIm, and ground select line driving signal lines GS0 to GS2 to the plurality of string select lines SSL0 to SSL2, the plurality of word lines WL0 to WLm, and the plurality of ground select lines GSL0 to GSL2, respectively.

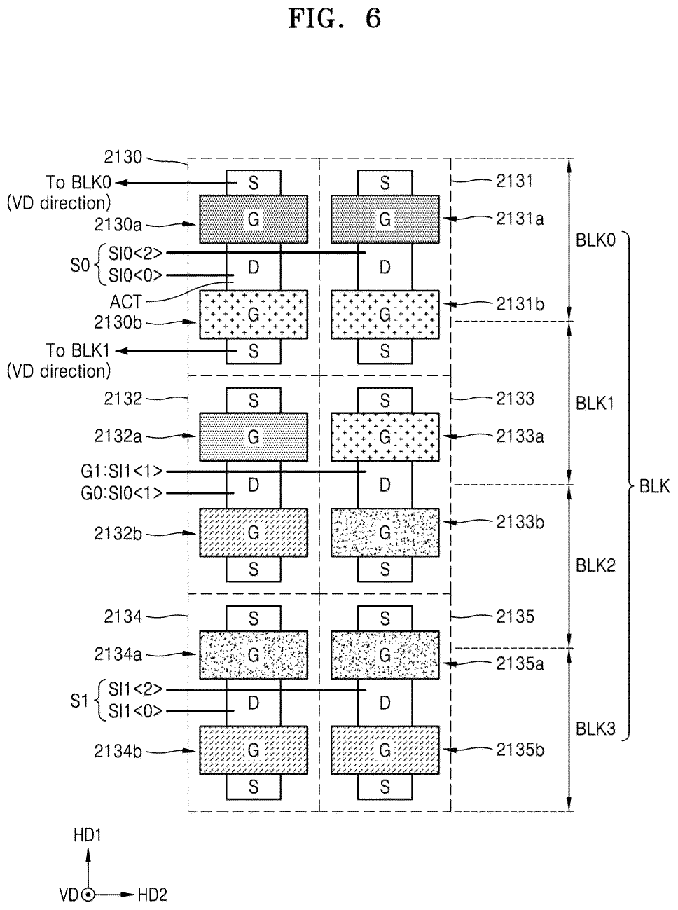

FIG. 6 is a top view illustrating a plurality of pass transistor blocks included in a pass transistor circuit and word line driving signal lines corresponding to the plurality of pass transistor blocks, according to an embodiment.

Referring to FIG. 6, a first pass transistor block 2130 to a sixth pass transistor block 2135 are disclosed. According to an embodiment, the first pass transistor block 2130 may include a first pass transistor 2130a and a second pass transistor 2130b. According to an embodiment, the first pass transistor block 2130 may include an active region ACT. In each of active regions ACT, one drain region D doped with a first conductive type, two source regions S, and two channel regions doped with a second conductive type may be formed. The drain region D may be at a central portion of the active region ACT in the first horizontal direction HD1. The two source regions S may be at both end portions of the active region ACT in the first horizontal direction HD1. Each channel region may be between the drain region D and a source region S. In each channel region, a gate electrode G may be formed on a gate insulating layer. Gate electrodes G may include a conductive material, such as polysilicon. In each active region ACT, two pass transistors, e.g., the first and second pass transistors 2130a and 2130b, sharing one drain region D may be formed. Two pass transistors, e.g., the first and second pass transistors 2130a and 2130b, sharing one drain region D may be connected to different memory blocks BLK. Pass transistors connected to one memory block BLK may be on two rows adjacent to each other. The description of two pass transistors, e.g., the first and second pass transistors 2130a and 2130b, may also be applied to two pass transistors included in each of the other transistor blocks in the same manner.

Although the present embodiment illustrates that two pass transistors are formed in one active region ACT, the present embodiment is not limited thereto. According to another embodiment, three or more pass transistors may be formed in one active region ACT.

Although the present embodiment illustrates that pass transistors connected to one memory block BLK are on two rows, the present embodiment is not limited thereto. Pass transistors connected to one memory block BLK may be on one row or three or more rows.

Referring to FIG. 6, the first pass transistor 2130a included in the first pass transistor block 2130, a first pass transistor 2131a included in the second pass transistor block 2131, and a first pass transistor 2132a included in the third pass transistor block 2132 may be a pass transistor corresponding to the first memory block BLK0. According to an embodiment, the pass transistor corresponding to the first memory block BLK0 may mean one of pass transistors configured to drive a plurality of word lines connected to the first memory block BLK0.

The second pass transistor 2130b included in the first pass transistor block 2130, a second pass transistor 2131b included in the second pass transistor block 2131, and a first pass transistor 2133a included in the fourth pass transistor block 2133 may be a pass transistor corresponding to the second memory block BLK1.

A second pass transistor 2132b included in the third pass transistor block 2132, a second pass transistor 2134b included in the fifth pass transistor block 2134, and a second pass transistor 2135b included in the sixth pass transistor block 2135 may be a pass transistor corresponding to a third memory block BLK2.

A second pass transistor 2133b included in the fourth pass transistor block 2133, a first pass transistor 2134a included in the fifth pass transistor block 2134, and a first pass transistor 2135a included in the sixth pass transistor block 2135 may be a pass transistor corresponding to a fourth memory block BLK3.

Referring to the embodiment of FIG. 6, the first pass transistor block 2130 to the sixth pass transistor block 2135 may be disposed in multiple steps. The first pass transistor 2130a, 2131a, 2132a, 2133a, 2134a, or 2135a and the second pass transistor 2130b, 2131b, 2132b, 2133b, 2134b, or 2135b included in each of the first pass transistor block 2130 to the sixth pass transistor block 2135 may share the active region ACT, and because one pass transistor block may be connected to different memory blocks, a memory block may be shared by different pass transistor blocks. Referring to FIG. 6, pass transistors included in one pass transistor block may be connected to different memory blocks.

Referring to FIG. 6, a first driving signal line SI0<0> may be connected to the drain region D of the first pass transistor block 2130. A third driving signal line SI0<2> may be connected to the drain region D of the second pass transistor block 2131. A second driving signal line SI0<1> may be connected to the drain region D of the third pass transistor block 2132. A fifth driving signal line SI1<1> may be connected to the drain region D of the fourth pass transistor block 2133. A fourth driving signal line SI1<0> may be connected to the drain region D of the fifth pass transistor block 2134. A sixth driving signal line SI1<2> may be connected to the drain region D of the sixth pass transistor block 2135.

According to an embodiment, the first driving signal line SI0<0> connected to the drain region D of the first pass transistor block 2130 and the third driving signal line SI0<2> connected to the drain region D of the second pass transistor block 2131 may be classified as an S0 group. According to an embodiment, driving signal lines included in the same group may be driven at the same timing. According to an embodiment, because the first pass transistor 2130a and the second pass transistor 2130b included in the first pass transistor block 2130 to which the first driving signal line SI0<0> is connected are the same as the first pass transistor 2131a and the second pass transistor 2131b included in the second pass transistor block 2131 to which the third driving signal line SI0<2> is connected, the first driving signal line SI0<0> and the third driving signal line SI0<2> may be classified as the same group.

According to an embodiment, the fourth driving signal line SI1<0> connected to the drain region D of the fifth pass transistor block 2134 and the sixth driving signal line SI1<2> connected to the drain region D of the sixth pass transistor block 2135 may be classified as an S1 group. According to an embodiment, because the first pass transistor 2134a and the second pass transistor 2134b included in the fifth pass transistor block 2134 to which the fourth driving signal line SI1<0> is connected are the same as the first pass transistor 2135a and the second pass transistor 2135b included in the sixth pass transistor block 2135 to which the sixth driving signal line SI1<2> is connected, the fourth driving signal line SI1<0> and the sixth driving signal line SI1<2> may be classified as the same group.

According to an embodiment, the second driving signal line SI0<1> connected to the drain region D of the third pass transistor block 2132 may be classified as a G0 group, and the fifth driving signal line SI1<1> connected to the drain region D of the fourth pass transistor block 2133 may be classified as a G1 group.

According to an embodiment, six driving signal lines connected to six pass transistor blocks may be classified into four groups according to applied timings.

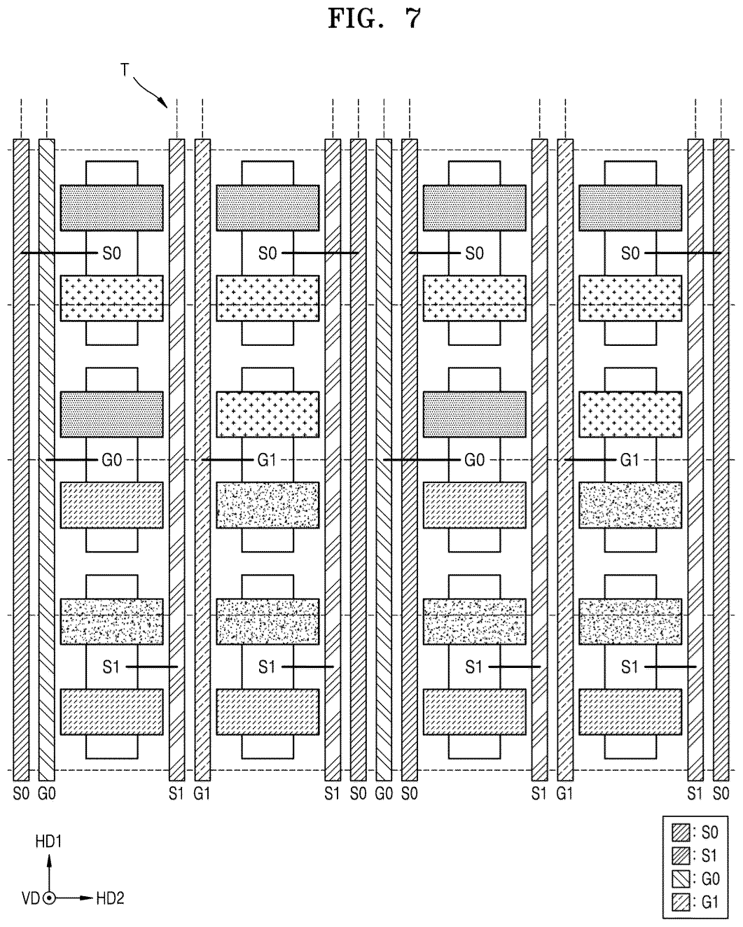

FIG. 7 is a top view illustrating an arrangement structure of driving signal lines connected to a plurality of pass transistor blocks, according to an embodiment.

In FIG. 7, for convenience of description, signal lines belonging to the same group are represented by a corresponding group. According to an embodiment, S0 lines shown in FIG. 7 may indicate driving signal lines belonging to the S0 group. S1 lines shown in FIG. 7 may indicate driving signal lines belonging to the S1 group. G0 lines shown in FIG. 7 may indicate driving signal lines belonging to the G0 group. G1 lines shown in FIG. 7 may indicate driving signal lines belonging to the G1 group. In the specification, a driving signal line may be a line for a signal applied to a word line pass transistor included in each of all pass transistor blocks or certain pass transistor blocks.

The group classification criterion in the specification may be an embodiment. According to another embodiment, a group may be classified with reference to signal lines to which a signal is applied at the same timing.

Referring to FIG. 7, a plurality of driving signal lines S0, G0, S1, and G1 connected to respective pass transistor blocks may be on a lower wiring layer or an upper wiring layer in a row decoder area.

Referring to FIG. 7, a plurality of wiring tracks T extending in the first horizontal direction HD1 and arranged at certain intervals in the second horizontal direction HD2 may be defined on the lower wiring layer or the upper wiring layer in the row decoder area. The plurality of wiring tracks T may be reference lines to arrange the plurality of driving signal lines S0, G0, S1, and G1. The plurality of driving signal lines S0, G0, S1, and G1 may be aligned with the plurality of wiring tracks T. Although FIG. 7 shows for convenience of description that the plurality of wiring tracks T are arranged at non-constant intervals, the plurality of wiring tracks T may be arranged at constant intervals.

Although FIG. 7 shows for convenience of description that pass transistor blocks do not overlap driving signal lines, according to another embodiment, the driving signal lines may extend in the first horizontal direction HD1 and overlap corresponding pass transistor blocks in the vertical direction VD.

Each of the plurality of driving signal lines S0, G0, S1, and G1 may be connected to the drain regions of corresponding pass transistors through contacts. According to an embodiment, a wiring layer on which the plurality of driving signal lines S0, G0, S1, and G1 are arranged may correspond to the top wiring layer used to arrange driving signal lines.

Alternatively, the plurality of driving signal lines S0, G0, S1, and G1 may be arranged on at least one of the remaining lower wiring layers except for the top low wiring layer.

Referring to FIG. 7, 12 pass transistor blocks are disclosed, and driving signal lines each connected to a pass transistor block are disclosed. According to an embodiment, for the plurality of driving signal lines S0, G0, S1, and G1, a signal applying timing may be different for each group.

According to an embodiment, there may exist a coupling capacitance between adjacent driving signal lines. The coupling capacitance may increase as the gap between driving signal lines decreases. In addition, the coupling capacitance may increase as the voltage change between driving signal lines increases.

As in the embodiment of FIG. 7, if driving signal lines driven at different timings are arranged adjacent to each other, the voltage change between the adjacent driving signal lines may increase, thereby increasing the coupling capacitance. According to embodiments, by arranging driving signal lines driven at the same timing so as to be adjacent to each other, the voltage change between the adjacent driving signal lines may be minimized, thereby decreasing the coupling capacitance and decreasing an ICC peak value.

As in the embodiment of FIG. 7, when pass transistor blocks are arranged in multiple steps in a structure of sharing a memory block, if driving signal lines are connected in an order of pass transistors, naturally, grouping of the driving signal lines may be impossible. In a structure of sharing a memory block, when a certain memory block is selected, instead that all driving signal lines are selected, only driving signal lines corresponding to the selected memory block are selected. In this case, if a driving signal line adjacent to a selected driving signal line is a non-selected driving signal line, the non-selected driving signal line acts as ground in terms of AC such that the area of the non-selected driving signal line which the selected driving signal line faces is viewed as a capacitance as it is, thereby exerting a bad influence on ICC of the selected driving signal line. In addition, because a driving signal line is supposed to be connected to all memory blocks or certain memory blocks, the driving signal line needs to extend by a length crossing all the memory blocks of one mat. Therefore, a viewed capacitance between wirings may not be small. In addition, along with an increase in the number of steps of word lines, pass transistors are disposed in multiple steps to reduce the area occupied by the pass transistors, and thus, discrimination of a selected driving signal line from a non-selected driving signal line is further complicated due to the multi-step arrangement. According to embodiments, the ICC peak of a driving signal line is reduced by a method of considering a wiring structure in which non-selected driving signal lines acting as AC ground are not arranged adjacent to selected driving signal lines when the selected driving signal lines are driven.

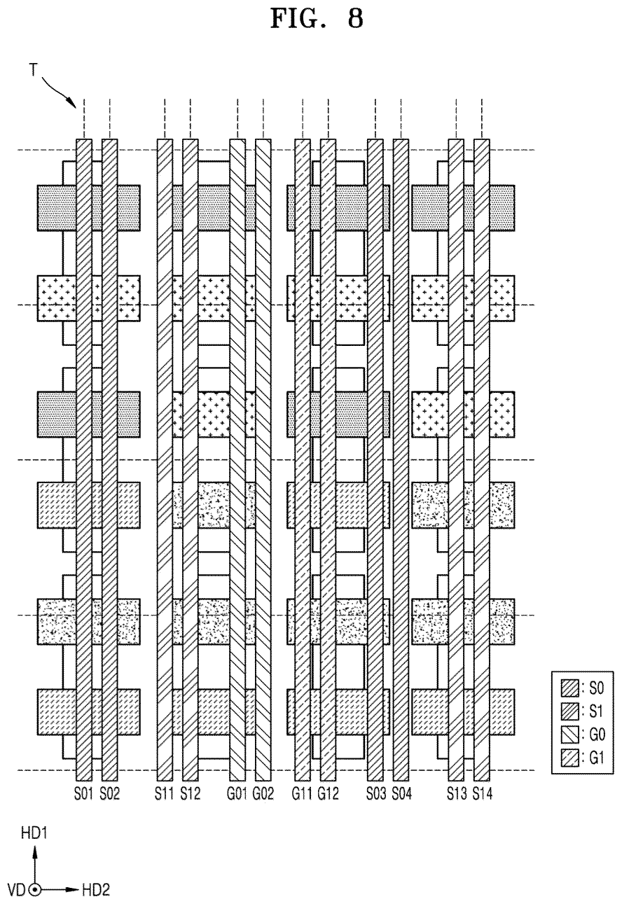

Arrangement structures of driving signal lines are described in more detail with reference to FIGS. 8 to 12. The arrangement structures of driving signal lines in FIGS. 8 to 12 are line arrangement structures on a metal layer.

FIG. 8 is a top view illustrating an arrangement structure in which a plurality of driving signal lines corresponding to a plurality of pass transistor blocks are arranged along certain track lines T, according to an embodiment.

According to an embodiment, all of first driving signal lines S01, S02, S03, and S04 belonging to an S0 group may be driven at a first timing. According to an embodiment, all of second driving signal lines S11, S12, S13, and S14 belonging to an S1 group may be driven at a second timing. According to an embodiment, all of third driving signal lines G01 and G02 belonging to a G0 group may be driven at a third timing. According to an embodiment, all of fourth driving signal lines G11 and G12 belonging to a G1 group may be driven at a fourth timing. In the specification, all of the first timing, the second timing, the third timing, and the fourth timing may be different timings from each other. According to one or more embodiments, driving signal lines driven at the same timing may be grouped. Grouping may indicate binding driving signal lines driven at the same timing and arranging the driving signal lines to be adjacent to each other.

Referring to FIG. 8, the first driving signal lines S01 and S02 belonging to the S0 group may be arranged on track lines T adjacent to each other, respectively. To the right of the first driving signal lines S01 and S02 belonging to the S0 group, the second driving signal lines S11 and S12 belonging to the S1 group may be sequentially arranged. To the right of the second driving signal lines S11 and S12 belonging to the S1 group, the third driving signal lines G01 and G02 belonging to the G0 group may be sequentially arranged. To the right of the third driving signal lines G01 and G02 belonging to the G0 group, the fourth driving signal lines G11 and G12 belonging to the G1 group may be sequentially arranged. To the right of the fourth driving signal lines G11 and G12 belonging to the G1 group, the first driving signal lines S03 and S04 belonging to the S0 group may be sequentially arranged. To the right of the first driving signal lines S03 and S04 belonging to the S0 group, the second driving signal lines S13 and S14 belonging to the S1 group may be sequentially arranged.

According to the embodiment of FIG. 8, two driving signal lines belonging to the same group may be arranged to be adjacent to each other. According to the embodiment of FIG. 8, in a plurality of driving signal lines, a driving signal line driven at the same timing may be arranged at one side of each driving signal line, and a driving signal line driven at a different timing may be arranged at the other side of each driving signal line. According to one or more embodiments, by arranging a driving signal line driven at the same timing at one side of each driving signal line, a voltage change at the one side may be reduced, thereby reducing a coupling capacitance.

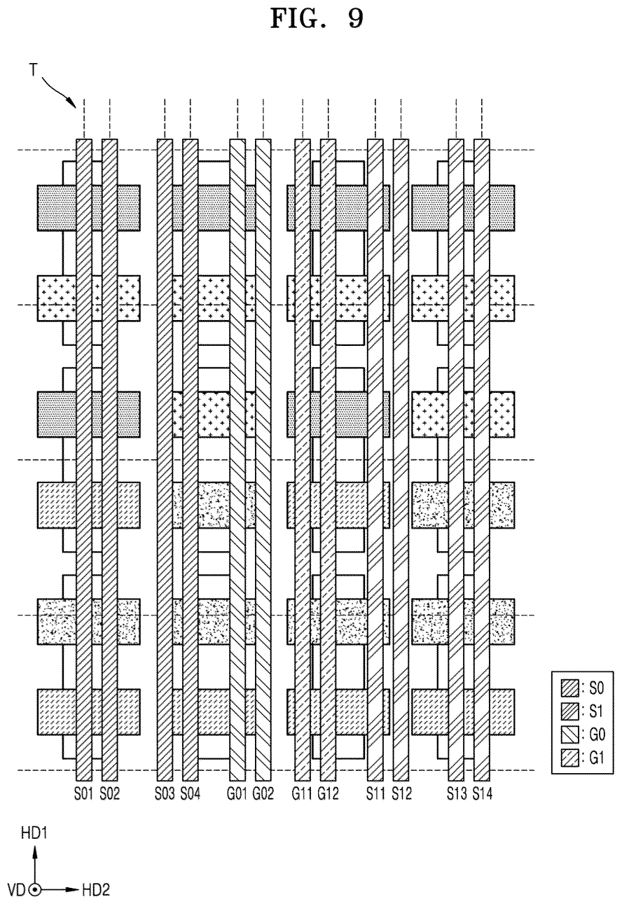

FIG. 9 is a top view illustrating an arrangement structure of driving signal lines, according to an embodiment.

The description made with reference to FIG. 8 is not repeated in a description of FIG. 9. Referring to FIG. 9, the first driving signal lines S01, S02, S03, and S04 belonging to the S0 group may be sequentially arranged on track lines T adjacent to each other, respectively. To the right of the first driving signal lines S01, S02, S03, and S04 belonging to the S0 group, the third driving signal lines G01 and G02 belonging to the G0 group may be sequentially arranged. To the right of the third driving signal lines G01 and G02 belonging to the G0 group, the fourth driving signal lines G11 and G12 belonging to the G1 group may be sequentially arranged. To the right of the fourth driving signal lines G11 and G12 belonging to the G1 group, the second driving signal lines S11, S12, S13, and S14 belonging to the S1 group may be sequentially arranged.

Referring to the embodiment of FIG. 9, compared to the embodiment of FIG. 8, three or more driving signal lines belonging to the same group may be sequentially arranged.

Referring to the embodiments of FIGS. 8 and 9, a driving signal line belong to the same group may be arranged at one or both sides of each driving signal line to be adjacent to each other. Referring to the embodiments of FIGS. 8 and 9, at least two driving signal lines belong to the same group may be arranged adjacent to each other. According to one or more embodiments, by arranging driving signal lines belonging to the same group in a row decoder to face each other, an ICC peak value may be reduced. Driving signal lines belonging to the same group may be driven at the same timing in response to the same signal from the row decoder. In the specification, the meaning that driving signal lines are adjacent to each other may indicate that one driving signal line is positioned at any one of both side track lines of the other driving signal line. According to another embodiment, the meaning that driving signal lines are adjacent to each other may indicate that the driving signal lines are arranged within a range less than or equal to the pitch value of a pass transistor. According to an embodiment, the arrangement structures of FIGS. 8 and 9 may be on an upper metal layer for connection to the row decoder.

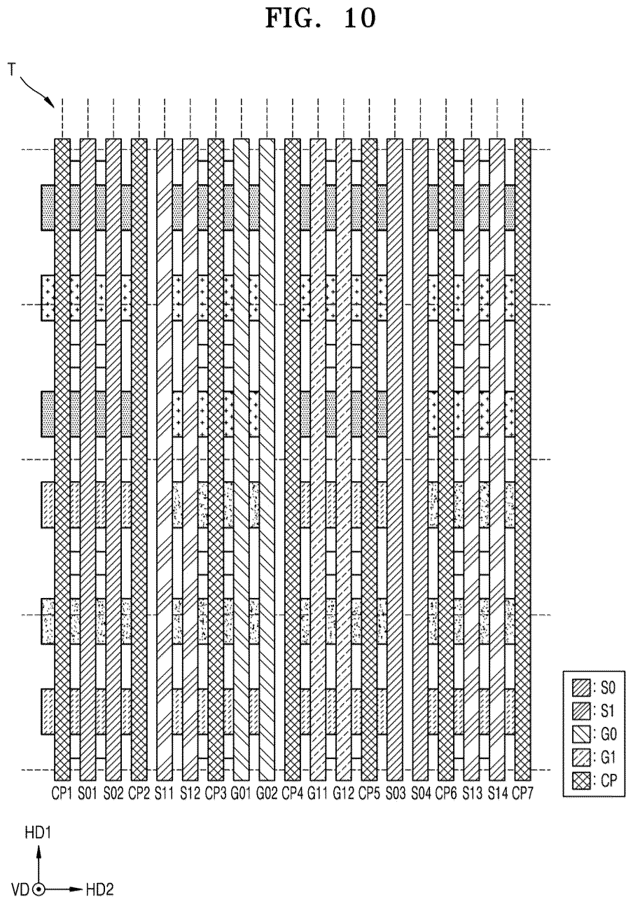

FIG. 10 is a top view illustrating an arrangement structure of additional signal lines, according to an embodiment.

The description made with reference to FIG. 8 is not repeated in a description of FIG. 10. Referring to FIG. 10, a first additional signal line CP1 to a seventh additional signal line CP7 belonging to an additional signal line group CP may be additionally arranged.

According to an embodiment, the first additional signal line CP1 may be at one side of the first driving signal line S01 belonging to the S0 group. The second additional signal line CP2 may be at the other side of the first driving signal line S02 belonging to the S0 group. The third additional signal line CP3 may be between the second driving signal line S12 belonging to the S1 group and the third driving signal line G01 belonging to the G0 group. The fourth additional signal line CP4 may be between the third driving signal line G02 belonging to the G0 group and the fourth driving signal line G11 belonging to the G1 group. The fifth additional signal line CP5 may be between the fourth driving signal line G12 belonging to the G1 group and the first driving signal line S03 belonging to the S0 group. The sixth additional signal line CP6 may be between the first driving signal line S04 belonging to the S0 group and the second driving signal line S13 belonging to the S1 group. The seventh additional signal line CP7 may be at the other side of the second driving signal line S14 belonging to the S1 group.

According to an embodiment, additional signal lines floating at a certain timing may be at sides of driving signal lines driven at the same timing. According to an embodiment, floating may indicate disconnection of a voltage generation signal and the like applied to an additional signal line.

According to an embodiment, the first additional signal line CP1 may be floating-processed at the same timing as the driving timing of the first driving signal line S01. According to an embodiment, the second additional signal line CP2 may be floating-processed at the same timing as the driving timing of the first driving signal line S02 or the second driving signal line S11. According to an embodiment, the third additional signal line CP3 may be floating-processed at the same timing as the driving timing of the second driving signal line S12 or the third driving signal line G01. According to an embodiment, the fourth additional signal line CP4 may be floating-processed at the same timing as the driving timing of the third driving signal line G02 or the fourth driving signal line G11. According to an embodiment, the fifth additional signal line CP5 may be floating-processed at the same timing as the driving timing of the fourth driving signal line G12 or the first driving signal line S03. According to an embodiment, the sixth additional signal line CP6 may be floating-processed at the same timing as the driving timing of the first driving signal line S04 or the second driving signal line S13. According to an embodiment, the seventh additional signal line CP7 may be floating- processed at the same timing as the driving timing of the second driving signal line S14. According to an embodiment, each of the first additional signal line CP1 to the seventh additional signal line CP7 may have the same length as each of the first to fourth driving signal lines.

Referring to FIG. 10, by arranging an additional signal line floating-processed at the same timing as the driving timing of a first driving signal line to be adjacent to the first driving signal line driven at a first timing, a voltage change may be reduced, thereby reducing a coupling capacitance.

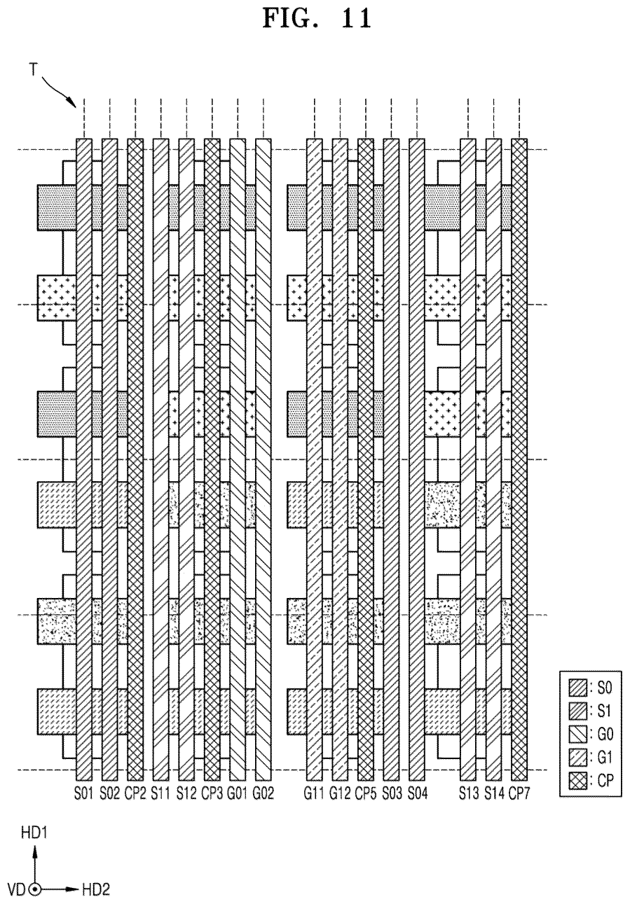

FIG. 11 is a top view illustrating an arrangement structure of additional signal lines, according to an embodiment.

The description made with reference to FIG. 10 is not repeated in a description of FIG. 11. Referring to the embodiment of FIG. 11, compared to the embodiment of FIG. 10, the first additional signal line CP1, the fourth additional signal line CP4, and the sixth additional signal line CP6 may not belong to the additional signal line group CP. The additional signal lines may be loaded in a variety of ways (for example, with an impedance to ground, an impedance in series, and/or an impedance at a far end).

Referring to the embodiment of FIG. 11, additional signal lines may be arranged at not both sides of grouped driving signal lines but only sides of some driving signal lines. According to an embodiment, such partial arrangement of additional signal lines may be performed by considering spare track lines T.

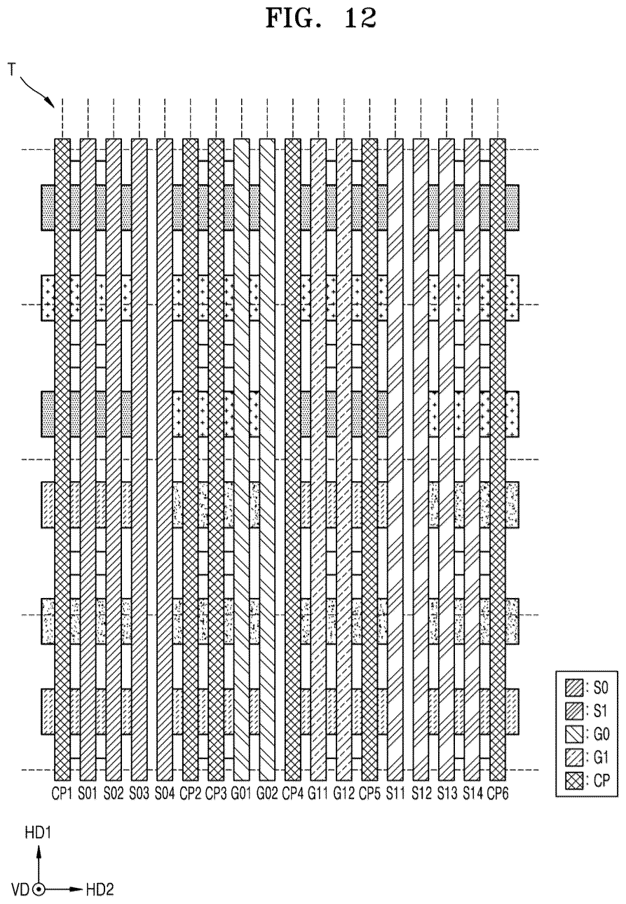

FIG. 12 is a top view illustrating an arrangement structure of additional signal lines, according to an embodiment.

The description made with reference to FIGS. 9 and 10 is not repeated in a description of FIG. 12. In the embodiment of FIG. 12, the arrangement structure of the first driving signal lines S01, S02, S03, and S04 belonging to the S0 group, the second driving signal lines S11, S12, S13, and S14 belonging to the S1 group, the third driving signal lines G01 and G02 belonging to the G0 group, and the fourth driving signal lines G11 and G12 belonging to the G1 group may be the same as the arrangement structure described with reference to FIG. 9.

Referring to the embodiment of FIG. 12, the first additional signal line CP1 is adjacent to the first driving signal line S01 belonging to the S0 group. The second additional signal line CP2 is adjacent to the first driving signal line S04 belonging to the S0 group. The third additional signal line CP3 is adjacent to the second additional signal line CP2. The third driving signal line G01 may be adjacent to the third additional signal line CP3.

According to an embodiment, the second additional signal line CP2 may be floating-processed at the driving timing of the first driving signal line S04 adjacent thereto, and the third additional signal line CP3 may be floating-processed at the driving timing of the third driving signal line G01 adjacent thereto.

Referring to the embodiment of FIG. 12, compared to the embodiment of FIG. 10, two additional signal lines may be between driving signal lines driven at different timings. In this case, because each floating processing may be performed at the driving timing of an adjacent driving signal line, a coupling capacitance may be further easily reduced.

Referring to the embodiments of FIGS. 10 to 12, a floating-processible additional signal line may be on a track line adjacent to a driving signal line. According to an embodiment, the arrangement structures of FIGS. 10 to 12 may be on a lower metal layer for connection to the row decoder.

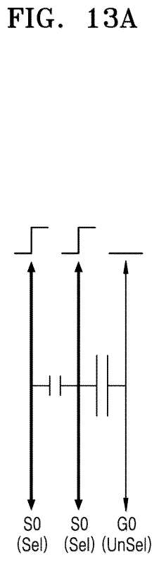

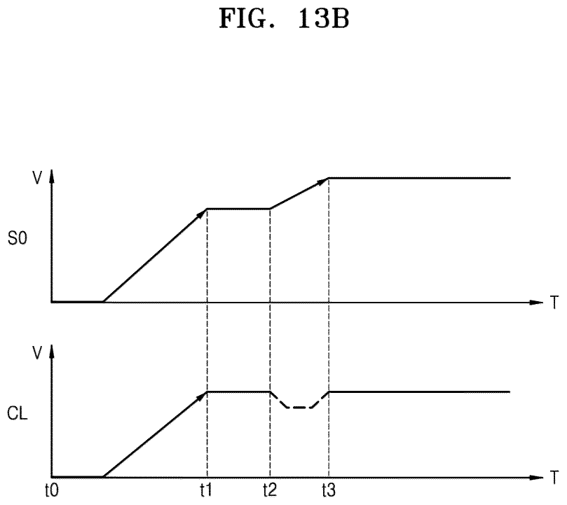

FIG. 13A illustrates a coupling capacitance between adjacent signal lines.

Referring to FIG. 13A, adjacent S0 lines may be simultaneously selected and thus simultaneously driven from a first level to a second level. However, a G0 line adjacent to an SO line may not be selected when the S0 line is selected, and accordingly, the G0 line may be AC ground-processed, thereby increasing a capacitance with the S0 line adjacent thereto. The large capacitor symbol in FIG. 13A indicates that there is a substantial leakage current from S0 to G0 at the time of driving S0. This leakage current tends, in a first instance, to be higher with S0 and G0 are different voltages. The leakage current also tends, in a second instance, to be higher when G0 offers a low impedance path, such as to ground. Driving G0 with the same voltage waveform as is driving S0 reduces leakage current in the first instance. Floating G0 so that it is at a high impedance tends to reduce leakage current in the second instance. Reducing leakage current in the first and/or second instance, reduces the peak Icc.

According to a comparative example, when a certain memory block is selected, an arrangement structure of driving signal lines may be irregular, and thus, an AC ground-processed line may be adjacent to a selected driving signal line, thereby not reducing an ICC peak value. According to one or more embodiments, when driving signal lines are driven, a signal line driven at the same timing as the driving timing of a selected driving signal line or floating-processed is adjacent to the selected driving signal line, and thus, a capacitance viewed from the selected driving signal line may be lower than the comparative example, thereby reducing an ICC peak value.

FIG. 13B shows timing diagrams illustrating a read operation of an additional signal line, according to an embodiment.

The upper timing diagram of FIG. 13B may be an operation timing diagram of a first driving signal line, i.e., an S0 line, and the lower timing diagram of FIG. 13B may be an operation timing diagram of an additional signal line adjacent to the S0 line.

According to an embodiment, in a first interval (t0 to t1), a boosting signal for driving a word line may be applied to the first driving signal line. In a second interval (t1 to t2), a first voltage level may be applied to the first driving signal line. In a third interval (t2 to t3), the first driving signal line may be boosted and driven from the first voltage level to a second voltage level to apply a word line voltage to the first driving signal line. In the third interval (t2 to t3), the additional signal line may be floating-processed. According to an embodiment, the additional signal line may be floating-processed during a word line setup time, i.e., a loading time for word lines.

That is, by floating-processing the additional signal line when the first driving signal line is driven in the third interval, the voltage level of the additional signal line may have a similar waveform to that of the voltage of the first driving signal line due to capacitive coupling. Accordingly, the first driving signal line may be little influenced by a coupling capacitance.

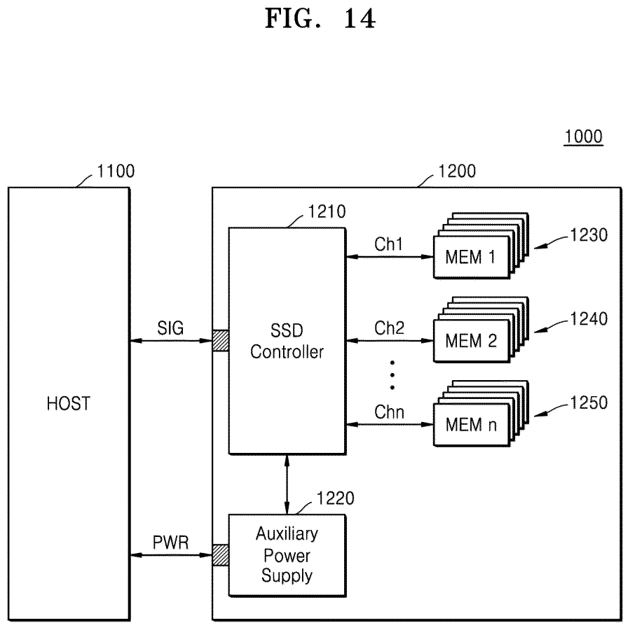

FIG. 14 is a block diagram illustrating an example in which a memory device according to some embodiments is applied to a solid state drive (SSD) system 1000.

Referring to FIG. 14, the SSD system 1000 may include a host 1100 and an SSD 1200. The SSD 1200 may transmit and receive a signal SIG to and from the host 1100 through a signal connector and receive power PWR from the host 1100 through a power connector. The SSD 1200 may include an SSD controller 1210, an auxiliary power supply 1220, and memory devices 1230, 1240, and 1250. The memory devices 1230, 1240, and 1250 may be vertically stacked NAND flash memory devices. In this case, the SSD 1200 may be implemented using the embodiments described above with reference to FIGS. 1 to 13B.

While example embodiments have been particularly shown and described, it will be understood that various changes in form and details may be made therein without departing from the spirit and scope of the following claims.

What is claimed is:

1. A memory device comprising:
a first driving signal line group comprising at least two first driving signal lines configured to be driven at a first timing;
a second driving signal line group comprising at least two second driving signal lines configured to be driven at a second timing different from the first timing; and
an additional signal line group comprising an additional signal line configured to be floating-processed at the first timing or the second timing,
wherein the first driving signal line group and the second driving signal line group are connected to a memory cell block via a pass transistor circuit.

2. The memory device of claim 1, wherein the at least two first driving signal lines are adjacent to each other, and the at least two second driving signal lines are adjacent to each other.

3. The memory device of claim 2, wherein the additional signal line group comprises at least one first additional signal line adjacent to the first driving signal line group.

4. The memory device of claim 2, wherein the additional signal line group comprises at least one second additional signal line adjacent to the second driving signal line group.

5. The memory device of claim 3, wherein the at least one first additional signal line is floating-processed at the first timing.

6. The memory device of claim 4, wherein the at least one second additional signal line is floating-processed at the second timing.

7. The memory device of claim 2, wherein the additional signal line is between the first driving signal line group and the second driving signal line group.

8. The memory device of claim 2, wherein a first length of the additional signal line is the same as a second length of each of the at least two first driving signal lines and the at least two second driving signal lines.

9. A memory device comprising:
a memory cell array comprising a plurality of memory blocks;
a plurality of driving signal lines respectively corresponding to a plurality of word lines stacked in a vertical direction;
a first additional signal line; and
a pass transistor circuit connected between the plurality of driving signal lines and the memory cell array,
wherein a first pass transistor included in the pass transistor circuit is provided as a structure sharing an active region with a second pass transistor adjacent to the first pass transistor,
wherein a first driving signal line of the plurality of driving signal lines is configured to be driven at a first timing and is connected to the active region of the first pass transistor and the second pass transistor, and in a metal wiring structure of the first driving signal line, and
wherein the first additional signal line is configured to be floating at the same timing as the first driving signal line and is arranged on a second line adjacent to the first driving signal line.

10. The memory device of claim 9, wherein the memory device comprises a third driving signal line in the metal wiring structure of the first driving signal line, and the third driving signal line is configured to be driven at the same timing as the first driving signal line and is adjacent to the first driving signal line.

11. The memory device of claim 10, wherein the memory device comprises a third additional signal line in the metal wiring structure of the first driving signal line, and the third additional signal line is configured to be floating at the same timing as the first driving signal line, and is adjacent to the third driving signal line.

12. A memory device comprising:
a memory cell array comprising a plurality of memory blocks;
a plurality of driving signal lines respectively corresponding to a plurality of word lines stacked in a vertical direction; and
a pass transistor circuit connected between the plurality of driving signal lines and the memory cell array,
wherein each of a plurality of pass transistor blocks included in the pass transistor circuit comprises two pass transistors sharing an active region, the plurality of pass transistor blocks comprise a respective plurality of active regions, different driving signal lines are respectively connected to the plurality of active regions of the plurality of pass transistor blocks, and
wherein the plurality of driving signal lines comprises:
a first driving signal line connected to a first active region and driven at a first timing;
a second driving signal line connected to a second active region and driven at a second timing;
a third driving signal line connected to a third active region and driven at the first timing;
a fourth driving signal line connected to a fourth active region and driven at the second timing, and
a first additional signal line adjacent to at least one of the first driving signal line and the third driving signal line.

13. The memory device of claim 12, wherein the first timing is different from the second timing.

14. The memory device of claim 13, wherein a metal wiring of the plurality of driving signal lines is arranged such that the first driving signal line is adjacent to the third driving signal line and the second driving signal line is adjacent to the fourth driving signal line.

15. The memory device of claim 14, wherein the first additional signal line is floating-processed at the first timing.

16. The memory device of claim 14, wherein the first additional signal line is boosting-processed at the first timing.

17. The memory device of claim 13, further comprising a second additional signal line adjacent to at least one of the second driving signal line and the fourth driving signal line.

18. The memory device of claim 17, wherein the second additional signal line is floating-processed at the second timing.

19. The memory device of claim 17, wherein the second additional signal line is boosting-processed at the second timing.

20. The memory device of claim 13, further comprising a second additional signal line adjacent to at least one of the second driving signal line and the fourth driving signal line,
wherein a first length of a first metal wiring of the first additional signal line and the second additional signal line is the same as a second length of a second metal wiring of the first to fourth driving signal lines.
